(19) United States
(12) Patent Application Publication
(10) Pub. No.: US 2015/0115294 A2
(43) Pub. Date: Apr. 30, 2015

(54) LIGHT EMITTING DEVICE INCLUDING RESIN-MOLDED BODY WITH WHITE PORTION AND BLACK PORTION

(71) Applicant: Nichia Corporation, Anan-shi, Tokushima (JP)

(72) Inventors: Takayuki IGARASHI, Yokohama-shi (JP); Ryo OISHI, Hamamatsu-shi (JP); Toshimasa TAKAO, Tokushima-shi (JP); Tetsuya YAGI, Anan-shi (JP)

(73) Assignee: Nichia Corporation, Anan-shi, Tokushima (JP)

(21) Appl. No.: 14/323,699

(22) Filed: Jul. 3, 2014

(30) Foreign Application Priority Data
Oct. 26, 2009 (JP) 2009-024957
Oct. 26, 2009 (JP) 2009-024958
Oct. 26, 2009 (JP) 2009-024959
Oct. 26, 2009 (JP) 2009-024960
Oct. 26, 2009 (JP) 2009-024961

(51) Int. Cl. H01L 33/56

(52) U.S. Cl. CPC H01L 33/56
USPC 257/88

(57) ABSTRACT

A light emitting device includes a resin-molded body including: a light emitting window, a white portion, and a black portion, wherein, in a top plan view of the light emitting device, the white portion surrounds the light emitting window, and the black portion surrounds the white portion; an electrode protruding from an outer surface of the resin-molded body; and
a plurality of light emitting elements mounted in an area surrounded by the white portion, the plurality of light emitting elements including at least two light emitting elements that are different in type from one another.

### CROSS-REFERENCE TO RELATED APPLICATIONS

The application is a continuation of U.S. Design Application No. 29/418,160, filed on Apr. 12, 2012, which is a divisional of U.S. Design Application No. 29/360,431, filed on Apr. 26, 2010, now U.S. Pat. No. D661,262 issued Jun. 5, 2012, both of which claim the benefit of foreign priority under 35 U.S.C. §119 to Japanese Design Application No. 2009-024961, Japanese Design Application No. 2009-024960, Japanese Design Application No. 2009-024959, Japanese Design Application No. 2009-024958, and Japanese Design Application No. 2009-024957, all filed on Oct. 26, 2009. All of these applications are hereby incorporated by reference in their entireties.

### BACKGROUND OF THE INVENTION

The present disclosure relates generally to light emitting element, and more particularly, to light emitting element having a resin-molded body.

### SUMMARY OF THE INVENTION

In one embodiment, a light emitting device includes a resin-molded body including: a light emitting window, a white portion, and a black portion, wherein, in a top plan view of the light emitting device, the white portion surrounds the light emitting window, and the black portion surrounds the white portion; an electrode protruding from an outer surface of the resin-molded body; and a plurality of light emitting elements mounted in an area surrounded by the white portion, the plurality of light emitting elements including at least two light emitting elements that are different in type from one another.

In one aspect, the white portion includes a recess, the recess having a top opening that forms the light emitting window.

In one aspect, one of the light emitting elements is positioned in a center of the recess.

In one aspect, the white portion and the black portion are flush at a top surface of the light emitting device.

In one aspect, the black portion forms a side surface of the resin-molded body.

In one aspect, the light emitting device includes three light emitting elements including first and second light emitting elements having heights that are substantially the same, and a third light emitting element having a height that is greater than the heights of the first and second light emitting elements.

In one aspect, the third light emitting element is positioned at an end of the area in which the light emitting element is mounted.

In one aspect, the first light emitting element is mounted on a first one of the electrodes, the second light emitting element is mounted on a second one of the electrodes, and the third light emitting element is mounted on a third one of the electrodes.

In one aspect, the light emitting device has six electrodes.

In one aspect, three electrodes protrude from a first side surface of the resin-molded body and remaining three electrodes protrude from a second side surface of the resin-molded body that opposes the first side surface.

In one aspect, the light emitting window has a rectangular shape with rounded corners.

In one aspect, the light emitting device further comprises a sealing resin filled in the recess and sealing the light emitting elements, the sealing resin being translucent.

In one aspect, the sealing resin is a milk-white color.

In one aspect, a lower region of a side surface of the resin-molded body is arranged inward of an upper region of the side surface of the resin-molded body, such that said side surface includes a step.

In one aspect, the electrode protrudes from the side surface at a location below the step.

In one aspect, the electrode bends downward.

In one aspect, the electrode does not protrude outward beyond the upper region of the side surface.

In one aspect, the resin-molded body has a first step located on a first side surface and a second step located on a second side surface that opposes the first side surface.

In one aspect, in a top plan view of the light emitting device, the resin-molded body has a rectangular shape with rounded corners.

In one aspect, in a side view of the light emitting device, the electrode has an outside portion that includes a wide section and a narrow section, the outside portion protruding from the outer surface of the resin-molded body at the narrow section.

In one aspect, the white portion has an upper section positioned above an exposed surface of the electrode and a lower section positioned below the exposed surface, an outer size of the lower section being smaller than an outer size of the upper section.

In one aspect, the white portion is exposed at a bottom surface of the light emitting device.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Embodiments of the invention are described by referring to the attached drawings, in which:

FIG. 1 is a front, top, right side perspective view of a light emitting device according to a first embodiment of the invention;

FIG. 2 is a front elevational view of the light emitting device depicted in FIG. 1;

FIG. 3 is a rear elevational view of the light emitting device depicted in FIG. 1;

FIG. 4 is a top plan view of the light emitting device depicted in FIG. 1;

FIG. 5 is a bottom plan view of the light emitting device depicted in FIG. 1;

FIG. 6 is a right side elevational view of the light emitting device depicted in FIG. 1;

FIG. 7 is a left side elevational view of the light emitting device depicted in FIG. 1;

FIG. 8 is a cross-sectional view of the light emitting device depicted in FIG. 1, taken along the line A-A shown in FIG. 4;

FIG. 9 is a rear, top, right side perspective view of a light emitting device according to a second embodiment of the invention;

FIG. 10 is a front, bottom, left side perspective view of the light emitting device depicted in FIG. 9;

FIG. 11 is a front elevational view of the light emitting device depicted in FIG. 9;

FIG. 12 is a rear elevational view of the light emitting device depicted in FIG. 9;

FIG. 13 is a top plan view of the light emitting device depicted in FIG. 9;

FIG. 14 is a bottom plan view of the light emitting device depicted in FIG. 9;

FIG. 15 is a right side elevational view of the light emitting device depicted in FIG. 9;

FIG. 16 is a left side elevational view of the light emitting device depicted in FIG. 9;

FIG. 17 is a front, top, right side perspective view of a light emitting device according to a third embodiment of the invention;

FIG. 18 is a front elevational view of the light emitting device depicted in FIG. 17;

FIG. 19 is a rear elevational view of the light emitting device depicted in FIG. 17;

FIG. 20 is a top plan view of the light emitting device depicted in FIG. 17;

FIG. 21 is a bottom plan view of the light emitting device depicted in FIG. 17;

FIG. 22 is a right side elevational view of the light emitting device depicted in FIG. 17;

FIG. 23 is a left side elevational view of the light emitting device depicted in FIG. 17;

FIG. 24 is a cross-sectional view of the light emitting device depicted in FIG. 17, taken along the line A-A shown in FIG. 20;

FIG. 25 is a front, top, right side perspective view of a light emitting device according to a fourth embodiment of the invention;

FIG. 26 is a front elevational view of the light emitting device depicted in FIG. 25;

FIG. 27 is a rear elevational view of the light emitting device depicted in FIG. 25;

FIG. 28 is a top plan view of the light emitting device depicted in FIG. 25;

FIG. 29 is a bottom plan view of the light emitting device depicted in FIG. 25;

FIG. 30 is a right side elevational view of the light emitting device depicted in FIG. 25;

FIG. 31 is a left side elevational view of the light emitting device depicted in FIG. 25;

FIG. 32 is a cross-sectional view of the light emitting device depicted in FIG. 25, taken along the line A-A shown in FIG. 28;

FIG. 33 is a front, top, right side perspective view of a light emitting device according to a fifth embodiment of the invention;

FIG. 34 is a front elevational view of the light emitting device depicted in FIG. 33;

FIG. 35 is a rear elevational view of the light emitting device depicted in FIG. 33;

FIG. 36 is a top plan view of the light emitting device depicted in FIG. 33;

FIG. 37 is a bottom plan view of the light emitting device depicted in FIG. 33;

FIG. 38 is a right side elevational view of the light emitting device depicted in FIG. 33; and

FIG. 39 is a left side elevational view of the light emitting device depicted in FIG. 33.

### DETAILED DESCRIPTION

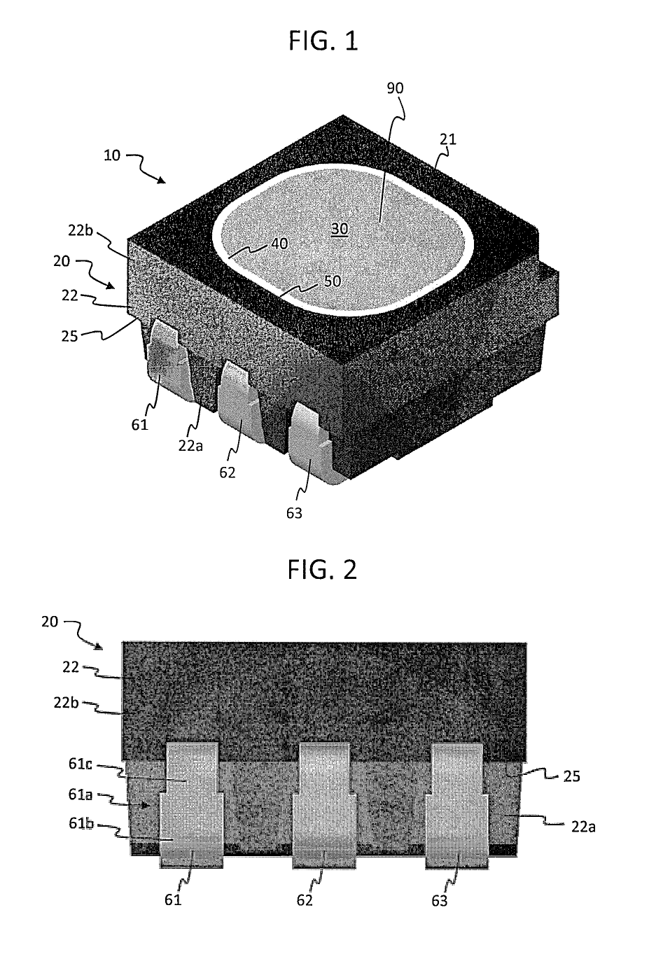

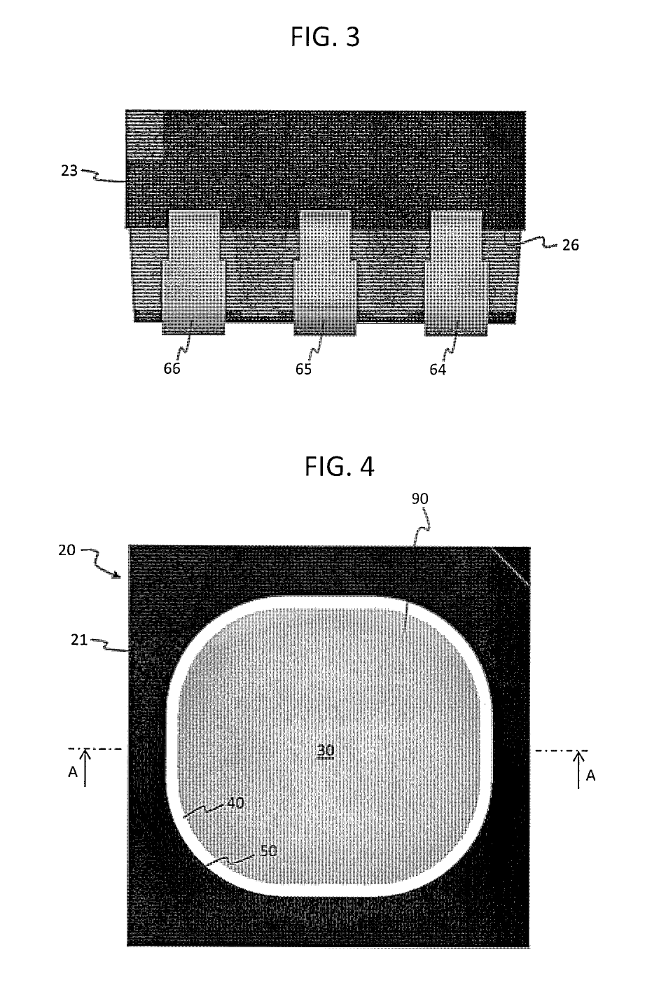

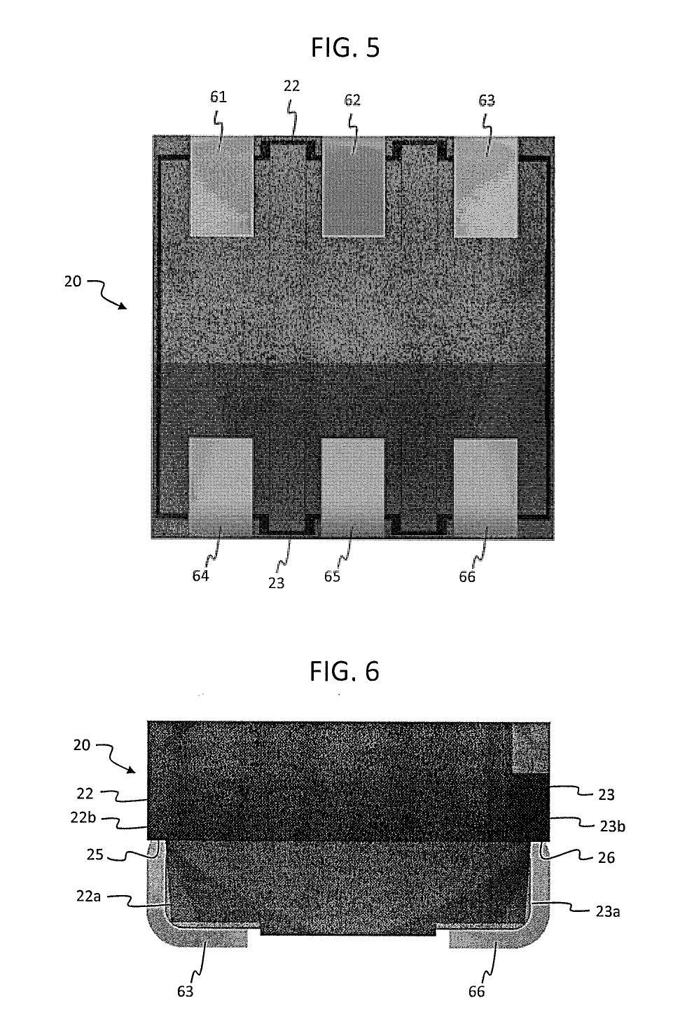

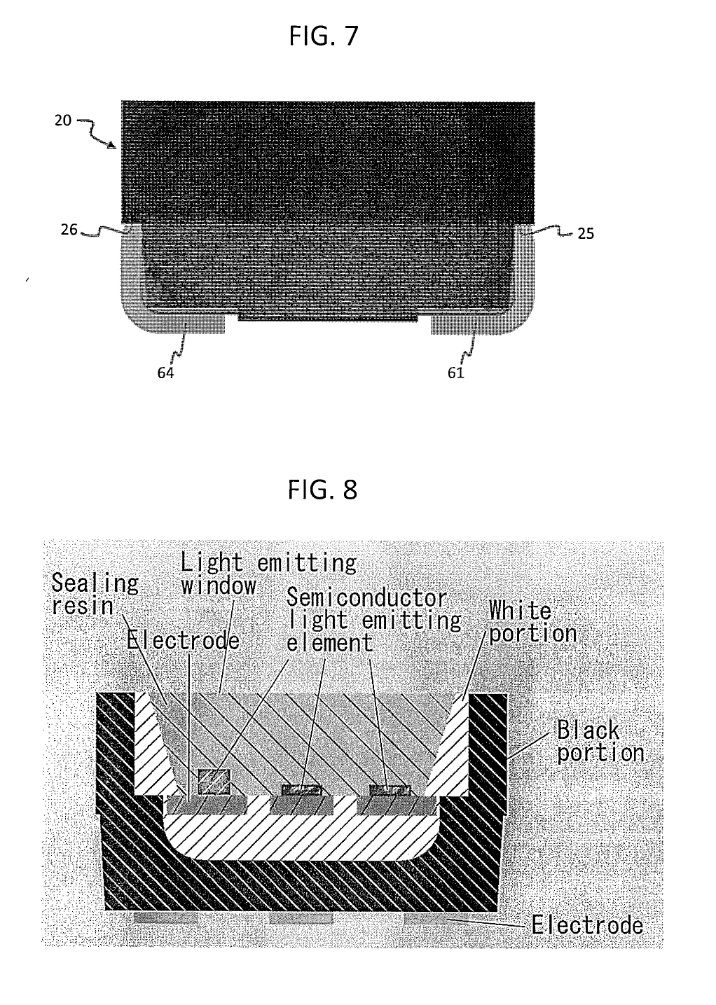

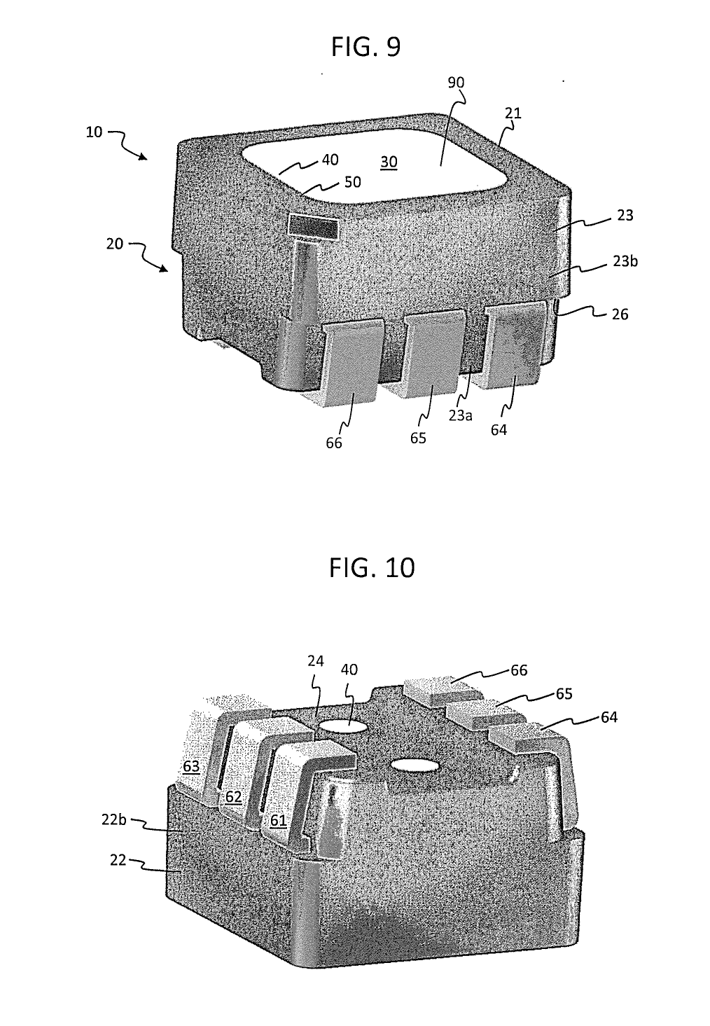

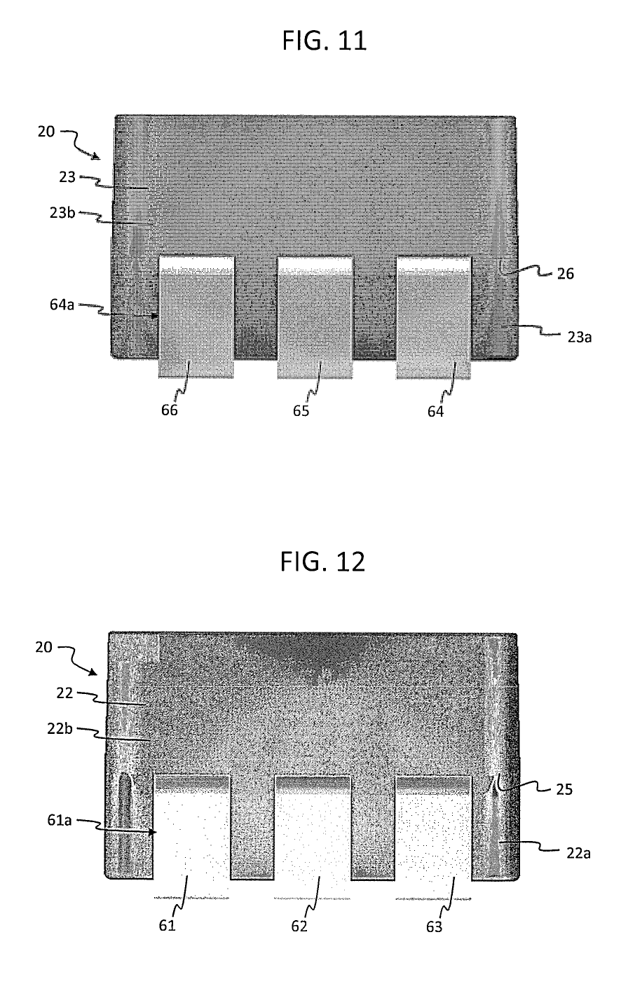

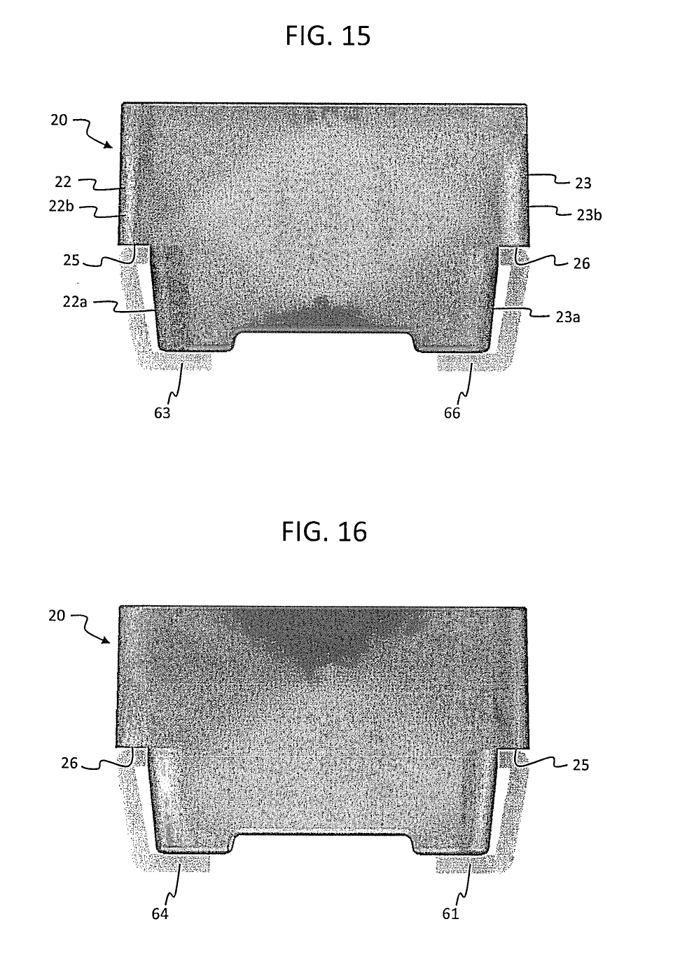

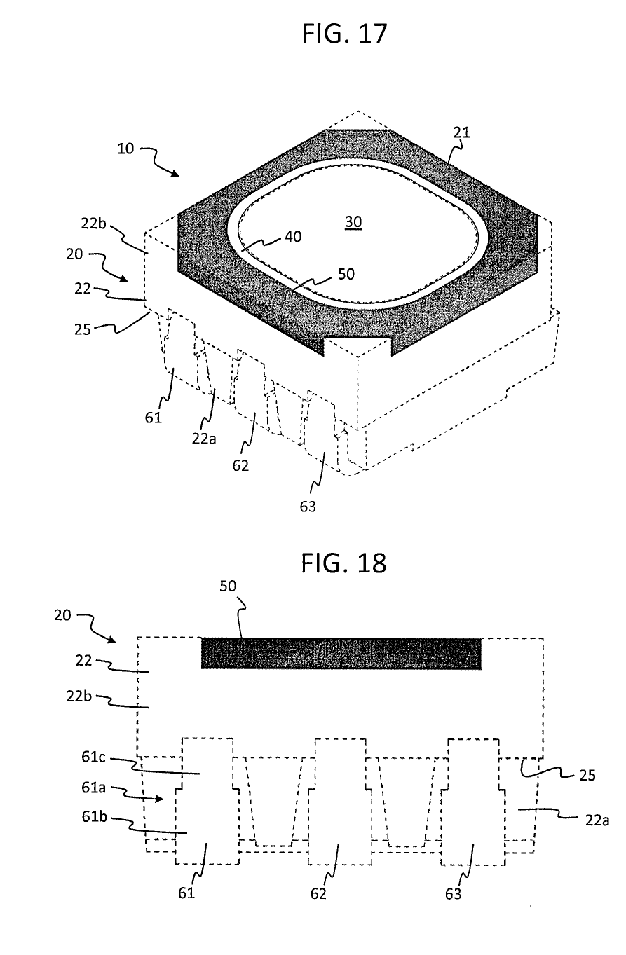

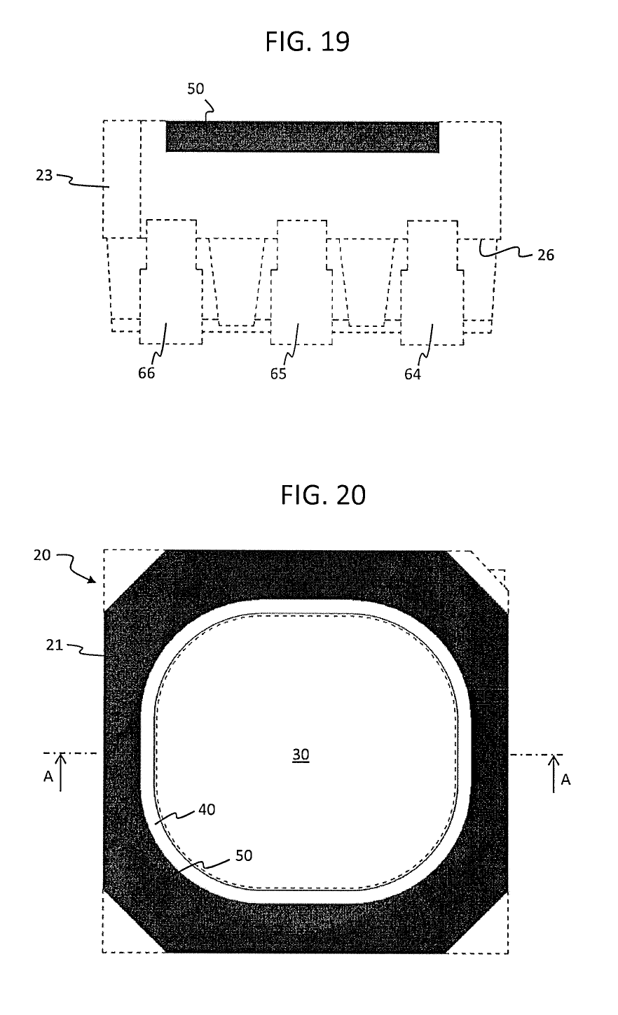

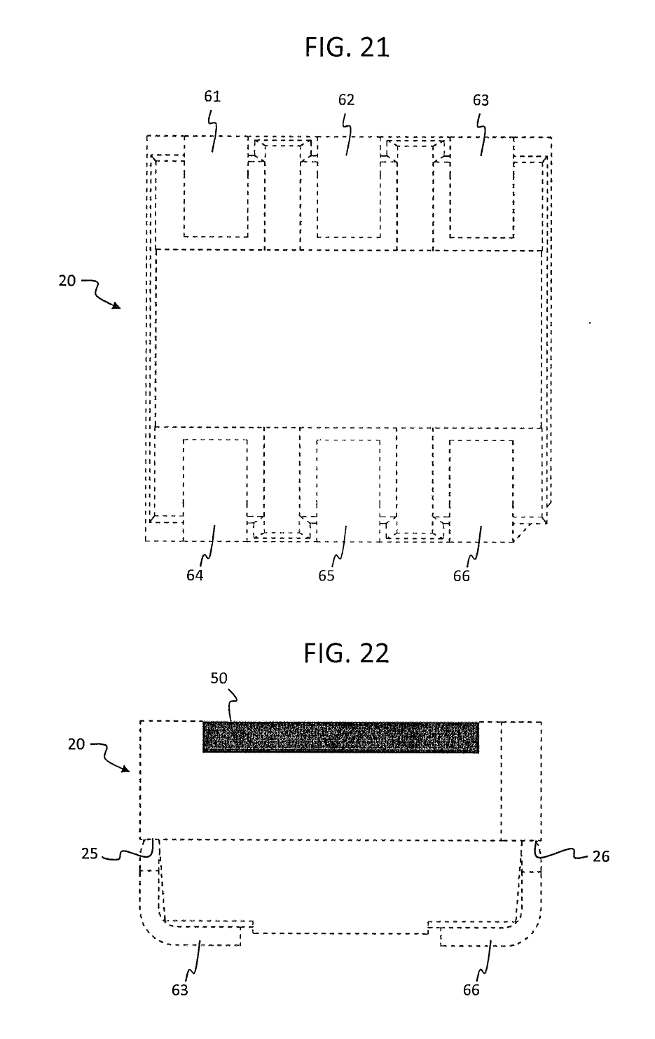

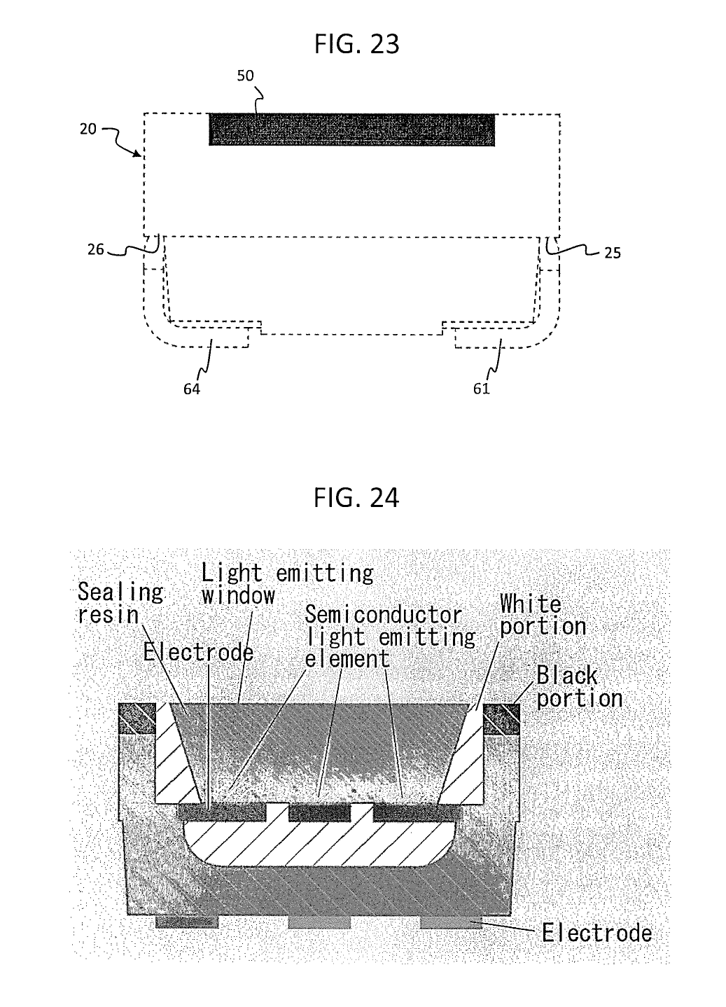

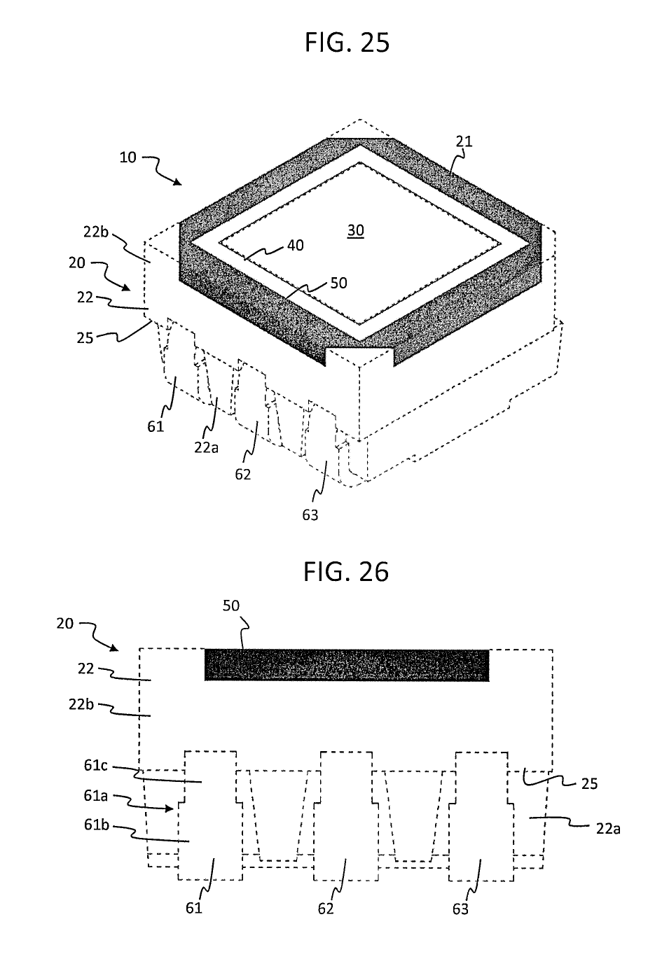

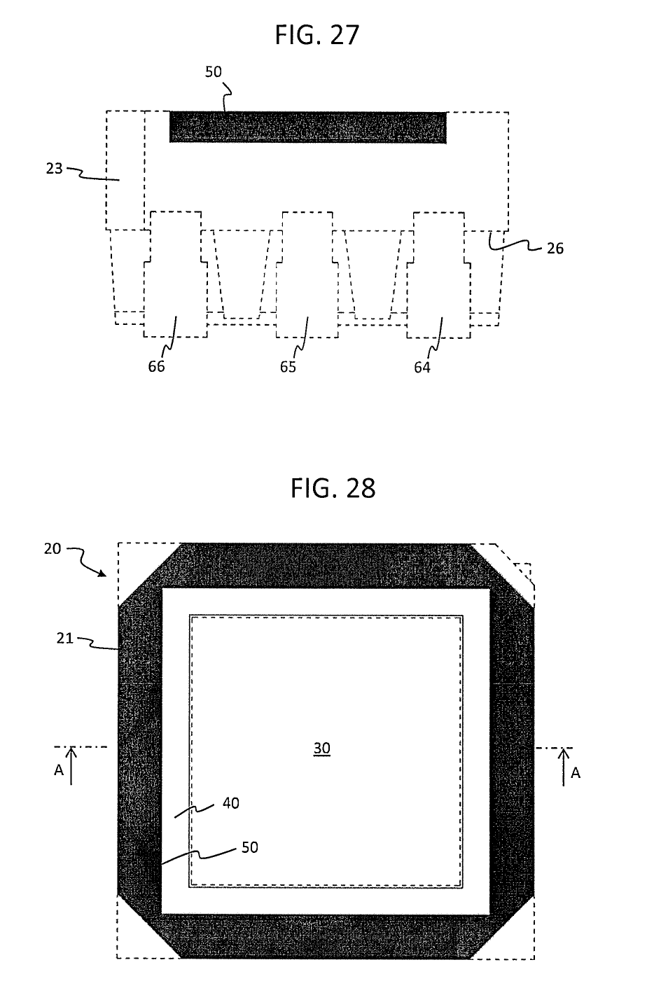

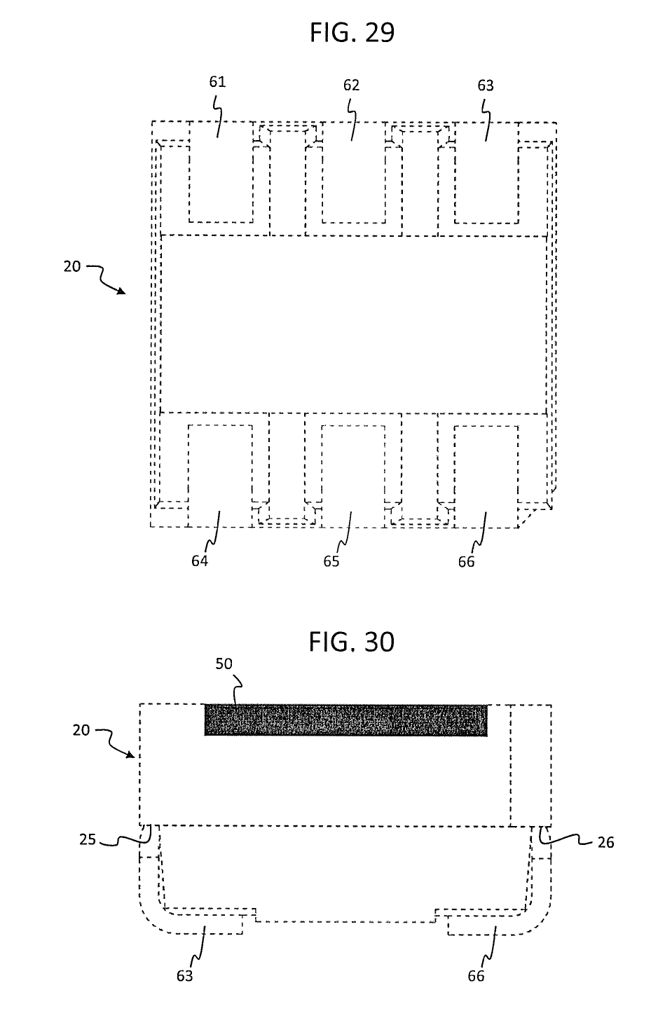

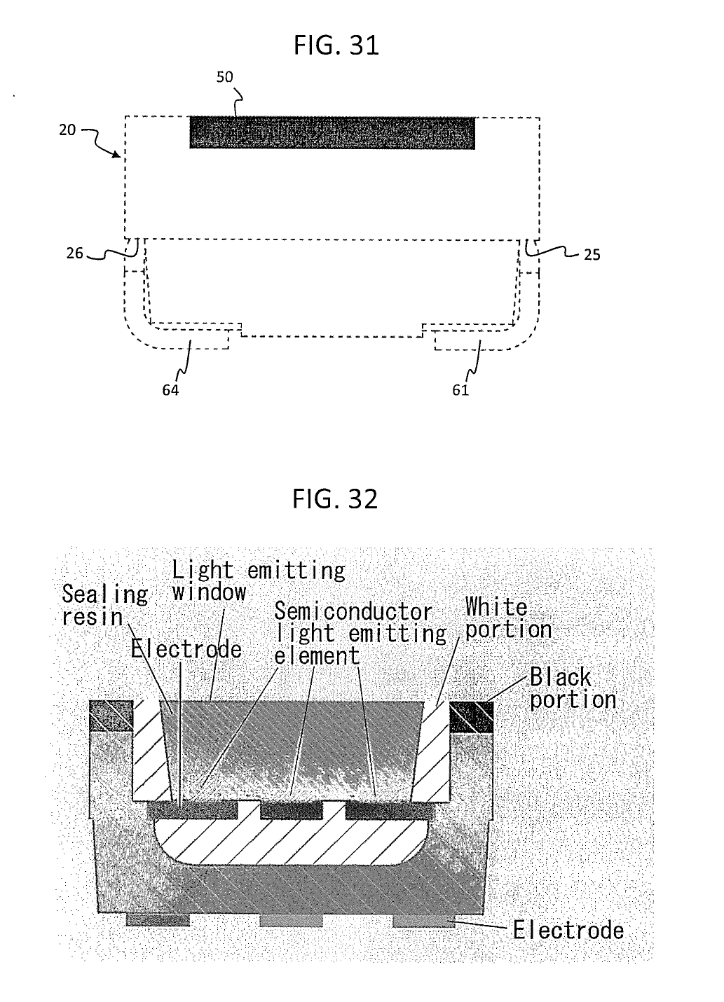

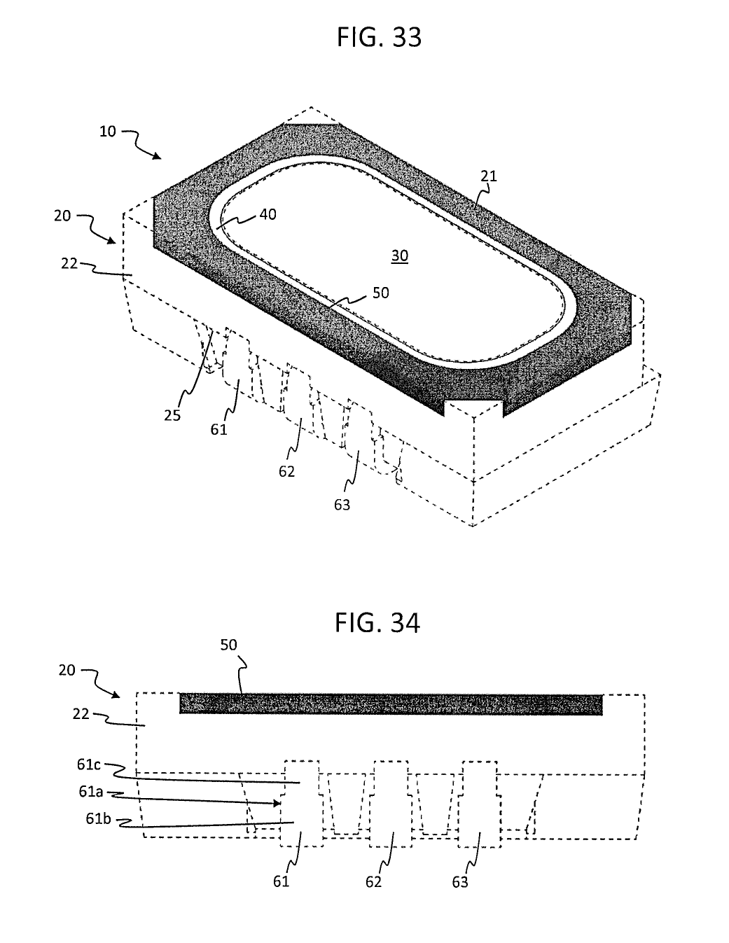

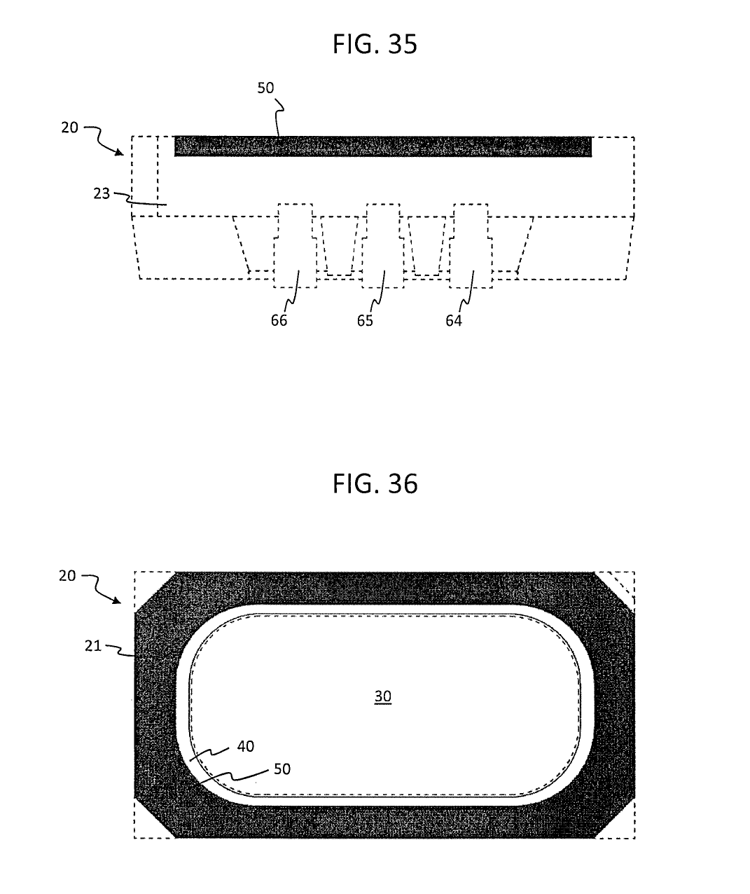

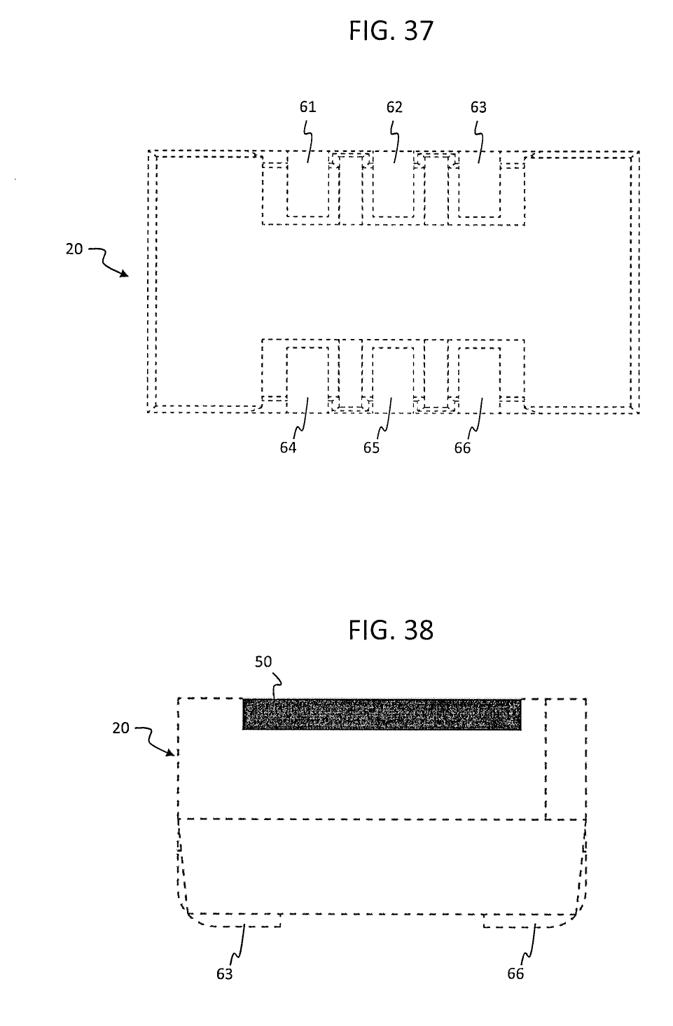

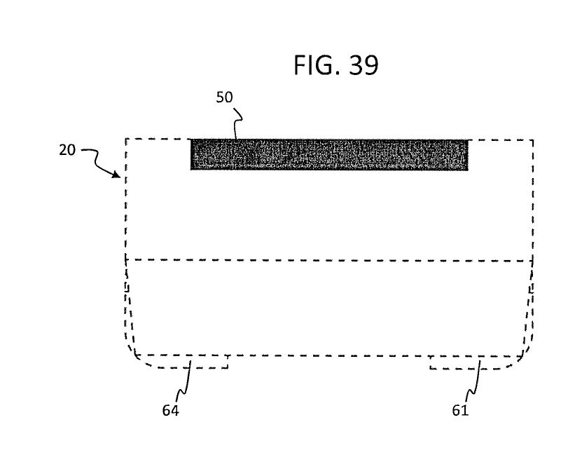

Referring to FIGS. 1-39, in one embodiment of the invention, a light emitting device 10 includes a resin-molded body 20. The resin-molded body 20 includes a light emitting window 30, a white portion 40, and a black portion 50. In a top plan view of the light emitting device, the white portion 40 surrounds the light emitting window 30, and the black portion 50 surrounds the white portion 40, as shown in FIGS. 4, 13, 20, 28, and 36. A plurality of light emitting elements are mounted in an area surrounded by the white portion 40, as shown in FIGS. 8, 24, and 32. The plurality of light emitting elements includes at least two light emitting elements that are different in type from one another, as also shown in FIGS. 8, 24, and 32. For example, in FIGS. 8, 24, and 32, the leftmost light emitting element is shown to be different in type from the center and rightmost light emitting elements.

In one aspect, the white portion 40 includes a recess, as shown in FIGS. 8, 24, and 32. The recess has a top opening that forms the light emitting window 30.

In one aspect, one of the light emitting elements is positioned in a center of the recess, as shown in FIGS. 8, 24, and 32.

In one aspect, the white portion 40 and the black portion 50 are flush at a top surface of the light emitting device 10, as shown in FIGS. 1, 8, 9, 17, 24, 25, 32, and 33.

In one aspect, the black portion 50 forms a side surface 22, 23 of the resin molded body 20, as shown in at least FIGS. 1-16.

In one aspect, the light emitting 10 includes three light emitting elements, including first and second light emitting elements having heights that are substantially the same (shown as the center and rightmost elements in FIGS. 8, 24, and 32), and a third light emitting element having a height that is greater than the heights of the first and second light emitting elements (shown as the leftmost element in FIGS. 8, 24, and 32).

In one aspect, the third light emitting element is positioned at an end of the area in which the light emitting element is mounted, as shown in FIGS. 8, 24, and 32.

In one aspect, the first light emitting clement is mounted on a first one 61 of the electrodes (also referred to as “terminals”), the second light emitting elements is mounted on a second one 62 of the electrodes, and the third light emitting element is mounted on a third one 63 of the electrodes, as shown in FIGS. 8, 24, and 32.

In one aspect, the electrodes 61, 62, 63 are partially exposed at the bottom of the recess surrounded by the white portion, and the light emitting elements are mounted on exposed surfaces of the electrodes 61, 62, 63, as shown in FIGS. 8, 24, and 32.

In one aspect, the light emitting device 10 has six electrodes 61, 62, 63, 64, 65, 66, as shown in FIGS. 1-39.

In one aspect, three electrodes 61, 62, 63 protrude from a first side surface 22 of the resin-molded body 20 and remaining three electrodes 64, 65, 66 protrude from a second side surface 23 of the resin-molded body 20 that opposes the first side surface 22, as shown in FIGS. 1-39.

In one aspect, the light emitting window 30 has a rectangular shape with rounded corners, as shown in FIGS. 1, 4, 9, 13, 17, 20, 33, and 36.

In one aspect, the light emitting device 10 further includes a sealing resin 90 filled in the recess and sealing the light emitting elements, as shown in FIGS. 1, 4, 8, 9, 13, 24, and 32. The sealing resin 90 is translucent. The sealing resin 90 may be a milk-white color, as shown, for example, in FIGS. 1, 4, 8, 9, and 13.

In one aspect, a lower region 22a, 23a of a side surface 22, 23 of the resin-molded body is arranged inward of an upper region 22b, 23b of the side surface 22, 23 of the resin-molded body 20, such that said side surface 22, 23 includes a step 25, 26, as shown, for example, in FIGS. 6, 7, 15, 16, 22, 23, 30, and 31.

In one aspect, the electrode 61, 62, 63, 64, 65, 66 protrudes from the side surface 22, 23 at a location below the step 25, 26, as shown, for example, in FIGS. 6, 7, 15, 16, 22, 23, 30, and 31.

In one aspect, the electrode 61, 62, 63, 64, 65, 66 bends downward, as shown in FIGS. 10, 15, and 16.

In one aspect, the electrode 61, 62, 63, 64, 65, 66 does not protrude outward beyond the upper region 22b, 23b of the side surface, as shown in FIGS. 6, 7, 15, 16, 22, 23, 30, and 31.

In one aspect, the resin-molded body 20 has a first step 25 located on a first side surface 22 and a second step 26 located on a second side surface 23 that opposes the first side surface 22, as shown, for example, in FIGS. 6, 7, 15, 16, 22, 23, 30, and 31.

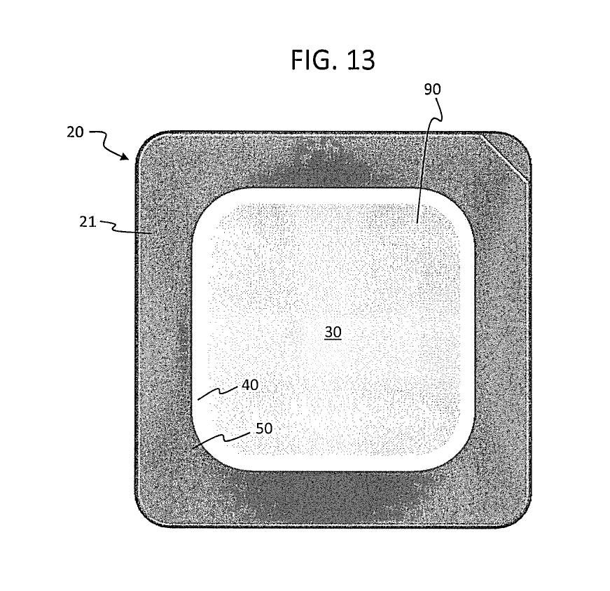

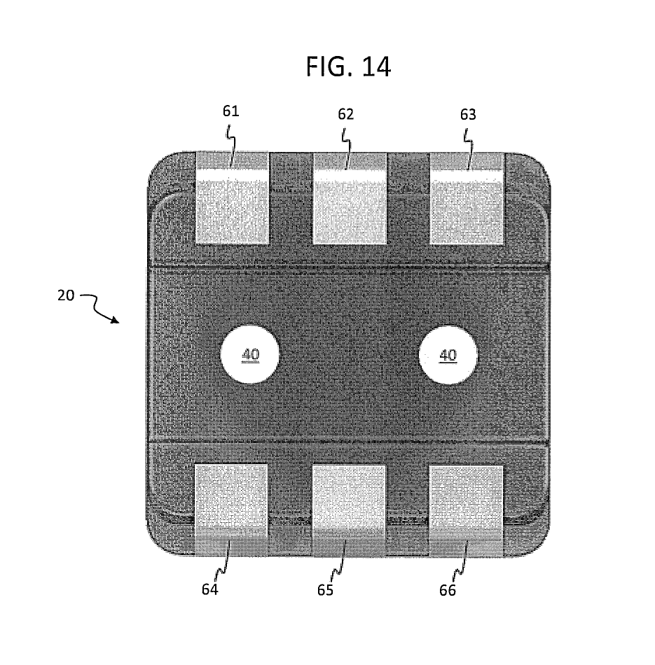

In one aspect, in a top plan view of the light emitting device 10, the resin-molded body 20 has a rectangular shape with rounded corners, as shown, for example, in FIGS. 13 and 14.

In one aspect, in a side view of the light emitting device, the electrode 61 has an outside portion 61a that includes a wide section 61b and a narrow section 61e, the outside portion 61a protruding from the outer surface 22 of the resin-molded body at the narrow section 61c, as shown in FIGS. 1-3, 17-19, and 25-27.

In one aspect, the white portion 40 has an upper section positioned above an exposed surface of the electrode and a lower section positioned below the exposed surface, an outer size of the lower section being smaller than an outer size of the upper section, as shown in FIGS. 8, 24, and 32.

In one aspect, the white portion 40 is exposed at a bottom surface of the light emitting device, as shown in FIGS. 8, 24, and 32.

What is claimed is:

1. A light emitting device comprising:
a resin-molded body including:
a light emitting window,
a white portion, and
a black portion,
wherein, in a top plan view of the light emitting device, the white portion surrounds the light emitting window, and the black portion surrounds the white portion;
an electrode protruding from an outer surface of the resin-molded body; and
a plurality of light emitting elements mounted in an area surrounded by the white portion, the plurality of light emitting elements including at least two light emitting elements that are different in type from one another.

2. The light emitting device according to claim I, wherein the white portion includes a recess, the recess having a top opening that forms the light emitting window.

3. The light emitting device according to claim 2, wherein one of the light emitting elements is positioned in a center of the recess.

4. The light emitting device according to claim 1, wherein the white portion and the black portion are flush at a top surface of the light emitting device.

5. The light emitting device according to claim 1, wherein the black portion forms a side surface of the resin-molded body.

6. The light emitting device according to claim 1, wherein the light emitting device includes three light emitting elements including first and second light emitting elements having heights that are substantially the same, and a third light emitting element having a height that is greater than the heights of the first and second light emitting elements.

7. The light emitting device according to claim 6, wherein the third light emitting element is positioned at an end of the area in which the light emitting element is mounted.

8. The light emitting device according to claim 6, wherein the first light emitting element is mounted on a first one of the electrodes, the second light emitting element is mounted on a second one of the electrodes, and the third light emitting element is mounted on a third one of the electrodes.

9. The light emitting device according to claim 1, wherein the light emitting device has six electrodes.

10. The light emitting device according to claim 9, wherein three electrodes protrude from a first side surface of the resin-molded body and remaining three electrodes protrude from a second side surface of the resin-molded body that opposes the first side surface.

11. The light emitting device according to claim 1, wherein the light emitting window has a rectangular shape with rounded corners.

12. The light emitting device according to claim 2, further comprising a sealing resin filled in the recess and sealing the light emitting elements, the sealing resin being translucent.

13. The light emitting device according to claim 12, wherein the sealing resin is a milk-white color.

14. The light emitting device according to claim 1, wherein a lower region of a side surface of the resin-molded body is arranged inward of an upper region of the side surface of the resin-molded body, such that said side surface includes a step.

15. The light emitting device according to claim 14, wherein the electrode protrudes from the side surface at a location below the step.

16. The light emitting device according to claim 15, wherein the electrode bends downward.

17. The light emitting device according to claim 16, wherein the electrode does not protrude outward beyond the upper region of the side surface.

18. The light emitting device according to claim 14, wherein the resin-molded body has a first step located on a first side surface and a second step located on a second side surface that opposes the first side surface.

19. The light emitting device according to claim 1, wherein, in a top plan view of the light emitting device, the resin-molded body has a rectangular shape with rounded corners.

20. The light emitting device according to claim 1, wherein, in a side view of the light emitting device, the electrode has an outside portion that includes a wide section and a narrow section, the outside portion protruding from the outer surface of the resin-molded body at the narrow section.

21. The light emitting device according to claim 2, wherein the white portion has an upper section positioned above an exposed surface of the electrode and a lower section positioned below the exposed surface, an outer size of the lower section being smaller than an outer size of the upper section.

22. The light emitting device according to claim 1, wherein the white portion is exposed at a bottom surface of the light emitting device.
